(19) United States
(12) Patent Application Publication
(10) Pub. No.: US 2023/0411417 A1
(43) Pub. Date: Dec. 21, 2023

(54) IMAGE SENSOR

(71) Applicant: Ningbo ABAX Sensing Electronic Technology Co., Ltd., Ningbo City (CN)

(72) Inventor: Shuyu LEI, Ningbo City, Zhejiang Province (CN)

(73) Assignee: Ningbo ABAX Sensing Electronic Technology Co., Ltd., Ningbo City, Zh (CN)

(21) Appl. No.: 18/033,388

(22) PCT Filed: Sep. 15, 2021
(86) PCT No.: PCT/CN2021/118376

§ 371 Date: Apr. 24, 2023

(30) Foreign Application Priority Data
Oct. 30, 2020 (CN) 202011187564.2
Oct. 30, 2020 (CN) 202011189656.4

(51) Int. Cl. H01L 27/146; G01S 7/481; G01S 17/894

(52) U.S. Cl. CPC H01L 27/14607; G01S 7/4816; G01S 17/894

(57) ABSTRACT

Provided is an image sensor, comprising a photodiode unit. The photodiode unit is used for receiving a return optical signal reflected back by a detected target; the photodiode unit is electrically connected to at least one corresponding memory cell in part of a time period by means of at least one transmission gate group, so as to transfer, to the at least one memory cell, photo-generated charge converted from the return optical signal; each of the at least one transmission gate group comprises at least two transmission gate units.

### CROSS REFERENCE TO RELATED APPLICATIONS

The present application claims priorities to Chinese Patent Application No. CN202011187564.2, titled “IMAGE SENSOR”, and Chinese Patent Application No. CN202011189656.4, titled “IMAGE SENSOR” filed on Oct. 30, 2020 with the Chinese Patent Office, both of which are incorporated herein by reference in their entireties.

### FIELD

The present disclosure relates to the technical field of image sensors, and particularly to a three-dimensional image sensor.

### BACKGROUND

In recent years, with the development of image sensors, higher requirements have been put forward for the miniaturization of image sensors, the efficiency of photoelectric conversion, and the rapid transfer of charges generated by conversion. In the traditional 2D imaging, the transfer time of internal charges is required to be compressed as much as possible to ensure the fast response of the sensor, but the charge transfer needs a certain amount of time under the existing image sensor design, otherwise resulting in incomplete transfer of the photogenerated charges and the residual image problem in the image acquisition.

With the development of the lidar technology, the Time of flight (TOF) technology has received more and more attention. The principle of the TOF is described as follows. A light pulse is continuously emitted to a target, and a light returned from the target is received by a sensor, and the distance to the target is obtained by detecting the flight (round-trip) time of the light pulse.

As the detection methods based on the TOF technology, the Direct Time of flight (DTOF) technology and the Indirect Time of flight (ITOF) technology have their own advantages in the use, and have received more and more attention.

The Indirect Time of flight technology is described as follows. In this technology, a phase difference relationship between an emission wave and a reflected echo of the detected object is acquired, and the distance information of the detected object is obtained based on the phase difference relationship. When using this method in 3D image acquisition with depth, in order to obtain a longer detection distance, a longer integration time is required, so that more photogenerated charges are generated, and in this case, more charges are required to be transferred. If the charge transfer speed is low, the time-of-flight distance information obtained through the detector array is inaccurate, resulting in inaccurate distance acquisition and affecting the use. In addition, two signals having complementary phases are generally used to control the transmission gate of the sensor in the acquisition of depth information. In this way, the return light signals with different phase information are transmitted to two different floating diffusion nodes (actually implemented as a storage unit). If the transmission gates controlled by the two complementary signals cannot transfer the signals corresponding to the return light rapidly and accurately in this process, there exists a difference in the basic information detected by the ITOF, which has a great impact on the whole detection result.

Therefore, an urgent problem to be solved in the design of two-dimensional and three-dimensional image sensors is to develop a storage unit that can rapidly transfer the photogenerated charges generated by the return light signal in the detector to be outputted.

### SUMMARY

In view of the above, an image sensor is provided in the present disclosure to improve the existing image sensor for the rapid transfer of photogenerated charges generated by the echo.

Technical solutions in the embodiments of the present disclosure are provided as follows.

An image sensor is provided. The image sensor includes a photodiode unit. The photodiode unit is configured to receive a return light signal reflected back by a detected target. The photodiode unit is electrically connected with at least one storage unit via one or more transmission gate groups for a part of a time period to transfer photogenerated charges converted by the return light signal to the at least one storage unit. Each of the one or more transmission gate groups includes at least two transmission gate units.

In an embodiment, the image sensor further includes a potential adjustment region, configured to accelerate the transfer of the photogenerated charges to the storage unit

In an embodiment, the number of the one or more transmission gate groups is two, and the number of the at least one storage unit is two.

In an embodiment, gates of the at least two transmission gate units in a same transmission gate group are connected together and are used to receive a same control signal.

In an embodiment, the storage unit is doped with a first type, and the image sensor further includes an epitaxial layer doped with a second type different from the doping type of the storage unit.

In an embodiment, the storage unit is doped with a first type, and the image sensor further includes an epitaxial layer doped with the first type the same as the doping type of the storage unit.

In an embodiment, the epitaxial layer of the first type is further connected with an auxiliary depletion layer.

In an embodiment, the number of the at least two transmission gate units in a same transmission gate group is even.

In an embodiment, the even number of transmission gate units in the same transmission gate group are symmetrically arranged on two sides of the photodiode unit.

In an embodiment, a line connecting the at least two transmission gate units symmetrically arranged is parallel to one of center lines of the photodiode unit.

In an embodiment, control signals respectively for the two transmission gate groups are complementary.

In an embodiment, the potential adjustment region is a doping region doped with a second type.

In an embodiment, the potential adjustment region is located in the epitaxial layer.

In an embodiment, the potential adjustment region is provided between the epitaxial layer and a first surface of the image sensor opposite to the epitaxial layer.

In an embodiment, the potential adjustment region extends from a first surface of the image sensor opposite to the epitaxial layer to a second surface of the image sensor.

The image sensor provided in the embodiment of the present disclosure includes a photodiode unit. The photodiode unit is configured to receive a return light signal reflected back by a detected target. The photodiode unit is electrically connected with at least one storage unit via one or more transmission gate groups for a part of a time period to transfer photogenerated charges converted by the return light signal to the at least one storage unit. Each of the one or more transmission gate groups includes at least two transmission gate units. With this design, the photogenerated charges generated by the photodiode unit receiving the returned light signal can be transferred to the corresponding storage unit (or may be a floating diffusion node herein) via the transmission gate group. Instead of the transmission gate unit, more than one transmission channel can be constructed from the photodiode unit to the floating diffusion node at the same time by the transmission gate group of the present disclosure, improving the transfer efficiency of photogenerated charges, so as to reduce the possibility of contradiction between high speed and high quality faced by the sensor in the following at the most basic level. In addition, the image sensor may further include a potential adjustment region configured to accelerate the transfer of the photogenerated charges to the storage unit. By adjusting the potential difference through the potential adjustment region, the potential characteristics in the diode can be rapidly changed, achieving the effect of rapid transfer of the photogenerated charges.

Details of one or more embodiments of the present disclosure are presented in the following drawings and descriptions. Other features, purposes and advantages of the present disclosure are apparent from the specification, drawings and claims.

### BRIEF DESCRIPTION OF THE DRAWINGS

In order to illustrate technical solutions of embodiments of the present disclosure more clearly, the drawings used for the embodiments are briefly introduced in the following. It should be understood that the drawings show only some embodiments of the present disclosure, and should not be regarded as a limitation of the scope. Other drawings may be obtained by those skilled in the art from these drawings without any creative work.

FIG. 1 is a schematic diagram showing a detection unit of an image sensor in the conventional technology;

FIG. 2 is a schematic diagram showing a sensor circuit for depth information acquisition according to an embodiment of the present disclosure;

FIG. 3 is a schematic diagram showing a sensor circuit for depth information acquisition according to another embodiment of the present disclosure;

FIG. 4 is a schematic diagram showing a sensor unit for depth information acquisition according to an embodiment of the present disclosure;

FIG. 5 is a sectional view of the sensor unit for depth information acquisition according to the embodiment of the present disclosure;

FIG. 6 is a schematic diagram showing a sensor unit for depth information acquisition according to another embodiment of the present disclosure;

FIG. 7 is a schematic diagram showing an effect of the sensor unit for depth information acquisition according to the embodiment of the present disclosure;

FIG. 8 is a schematic diagram showing effect comparison between the sensor unit according to the embodiment of the present disclosure and an existing sensor;

FIG. 9 is a schematic diagram showing a sensor unit for depth information acquisition according to another embodiment of the present disclosure;

FIG. 10 is a schematic diagram showing a sensor unit for depth information acquisition according to another embodiment of the present disclosure;

FIG. 11 is a schematic diagram showing a doping region for assisting transfer provided in a sensor unit according to an embodiment of the present disclosure;

FIG. 12 is a schematic diagram showing a doping region for assisting transfer provided in a sensor unit according to another embodiment of the present disclosure;

FIG. 13 is a schematic diagram showing a doping region for assisting transfer provided in a sensor unit according to another embodiment of the present disclosure; and

FIG. 14 is schematic diagram showing a cross-sectional potential distribution effect under a structure of the doping region for assisting transfer shown in FIG. 11 according to the embodiment of the present disclosure.

### DETAILED DESCRIPTION OF EMBODIMENTS

In order to make objects, technical solutions and advantages of the embodiments of the present disclosure clearer, the technical solutions in the embodiments of the present disclosure are clearly and completely described below with reference to the drawings in the embodiments of the present disclosure. Apparently, the described embodiments are some but not all embodiments of the present disclosure. Components of the embodiments generally described and illustrated in the drawings herein may be arranged and designed in a variety of different configurations.

Therefore, the following detailed description for the embodiments of the present disclosure provided in the drawings is not intended to limit the scope of the present disclosure as claimed, but is merely representative of selected embodiments of the present disclosure. Based on the embodiments in the present disclosure, all other embodiments obtained by those skilled in the art without creative work shall fall in the protection scope of the present disclosure.

It should be noted that, similar numerals and letters refer to similar items in the following drawings. Therefore, if an item is defined in a drawing, the item is not required to be further defined and explained in subsequent drawings.

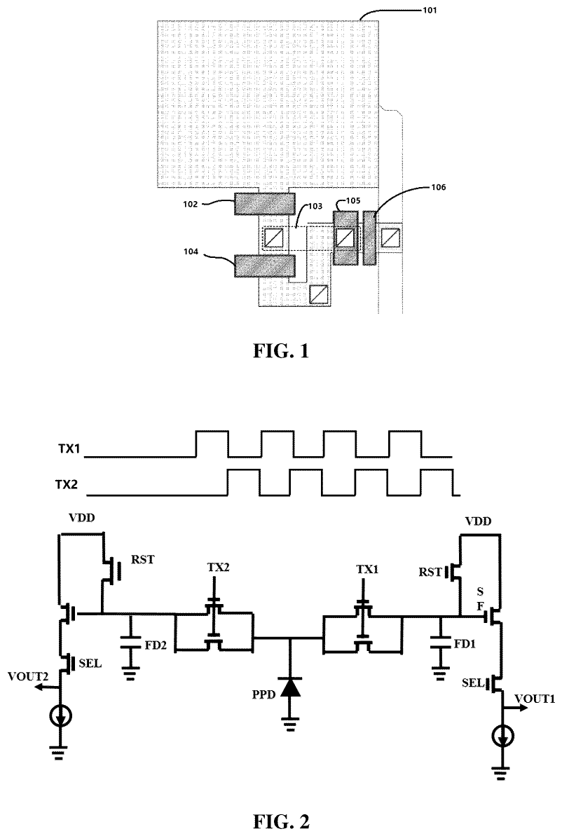

FIG. 1 is a schematic diagram showing a detection unit of an image sensor in the conventional technology. As shown in FIG. 1, an existing image sensor generally has a 4T structure, where a reference numeral 101 denotes a photodiode unit. A returned light signal may be converted into photogenerated charges (including electrons, holes, or the like. For efficient transmission, the photogenerated charges generally refer to photogenerated electrons, but are not specifically limited to the photogenerated electronics) in a photoelectric conversion region of the photodiode unit. A reference numeral 102 denotes a transmission gate, which may be generally implemented by a transistor, and is not limited herein. A control signal is applied to a gate electrode of the transmission gate 102, so that the photogenerated charges generated in the photodiode unit are transferred to a floating diffusion node 103. When the voltage is applied to a gate electrode of a readout transistor 105, the photogenerated charges in the floating diffusion node may be transferred to a readout circuit, and thus corresponding information is outputted by a subsequent circuit. A reference numeral 104 denotes a reset transistor, which is used to perform the reset of the sensor unit. A reference numeral 106 denotes a row selection transistor, which is used to transmit row selection information. In a case that a row is selected, a gate electrode of the row selection transistor may be controlled by a control signal at a high level. It is clear from the above description that, the transmission gate 102 is essential for the transfer of the generated charges of the image sensor unit. In FIG. 1, the transmission gate is arranged at a corner of the photodiode. Further, in the industry, the transmission gate may be arranged at different edges or different corners in the layout. However, the above arrangement results in a limited action range of the transmission gate. For a long distance, since the electric potential change is relative small, the charges generated by the echo are relative few. Under the requirements for rapid information acquisition and processing of the detector, the defect of this design more and more affects the high quality and efficiency of the detector. Therefore, an image sensor that can improve the transfer efficiency is needed to meet the increasing requirements for the performance of the image sensor. FIG. 1 shows a schematic diagram of a traditional two-dimensional image sensor. A traditional pixel structure for depth information acquisition is implemented by adding a complementary phase control module to the structure shown in FIG. 1. In actual operation, only one transmission gate works at a certain time. In this case, a problem that the photogenerated charges cannot be transferred rapidly and completely may occur, so that the most basic detection information may be deviated, and thus cannot meet the requirements of high-speed and accurate acquisition of three-dimensional information.

In order to solve the above problem existing in the conventional technology, the structure of the transmission gate is replaced with a transmission gate group in the design of the pixel unit in the present disclosure. FIG. 2 is a schematic diagram showing a sensor circuit for depth information acquisition according to an embodiment of the present disclosure. It can be seen from the circuit that, a structure of a transmission gate group is used in the present disclosure, and each transmission gate group includes at least two transmission gate units, and control signals respectively for the two transmission gate units are the same. For example, the two transmission gate groups in FIG. 2 are respectively denoted by TX1 and TX2. In order to achieve efficient depth information measurement with the ITOF, two transmission gate groups are required. The TX1 and TX2 each receive two control signals having complementary phases. For example, the control signal for the TX1 is a signal having a receiving phase difference of 0° or 90°, and the control signal for the TX2 is a signal having a phase difference of 1800 or 270°. In this way, the signal channels of the two transmission gates are complementary, achieving the effect of efficient detection. In order to ensure that each phase information can be efficiently and rapidly transferred to a corresponding storage unit (a first floating diffusion node FD1 and a second floating diffusion node FD2), the first transmission gate group TX1 receives the 0° or 90° phase difference signal to be controlled, and the second transmission gate group TX2 receives the 180° or 270° phase difference signal to be controlled. Gate electrodes of the transmission gate units in the same transmission gate group are connected together, so that the transmission channels between the photodiode and the floating diffusion node are changed into two groups in parallel, which can not only increase the number of transfer channels, but also change the potential distribution characteristics in the photodiode in a wider range, so as to accelerate the electron transfer. The sensor unit that obtains the three-dimensional depth information is illustrated above as an example. Further, a two-dimensional image sensor may be used, so as to reduce a residual image problem of the acquired image, and other parts thereof are the same as those in the conventional technology, which are not repeated herein.

FIG. 3 is a schematic diagram showing a sensor circuit for depth information acquisition according to another embodiment of the present disclosure. The solution shown in FIG. 3 differs from the solution shown in FIG. 2 in that the number of transmission gate units in each transmission gate group is 4, which further increases the number of transmission channels between the photodiode and the floating diffusion node, and further increases the affected range of the potential in the photodiode. The number of transmission gates is not limited in the implementation, which may be set as 3, 5, 6, and so on.

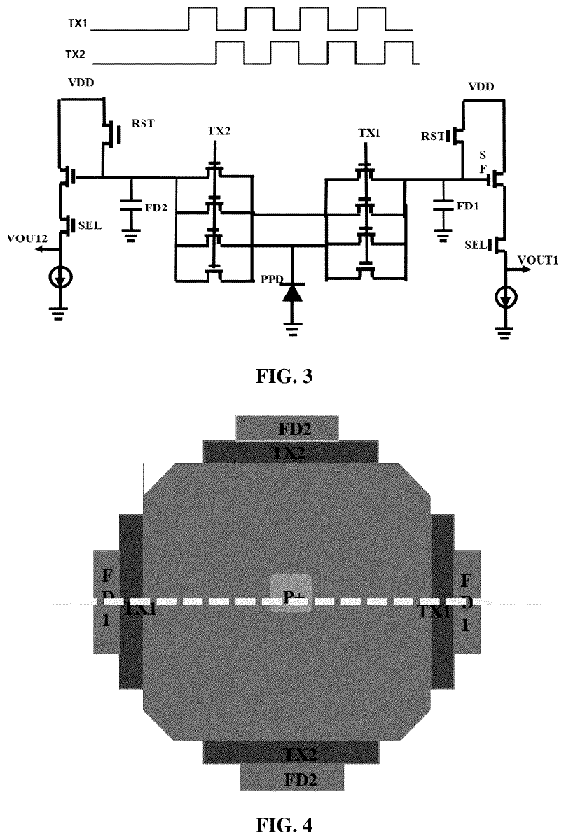

FIG. 4 is a schematic diagram showing a sensor unit for depth information acquisition according to an embodiment of the present disclosure. It is easy to see from the drawings that, in order to achieve the solution of the transmission gate group including two transmission gate units shown in FIG. 2, sub-transmission gate units of the transmission gate are arranged on the opposite sides of the photoelectric element, such as two relatively arranged transmission gate units TX1 and two relatively arranged transmission gate units TX2 in FIG. 4. In this way, the two transfer directions of the same transmission gate group are located in different directions, similar to a teeterboard structure, so that the probability of rapid transfer of the photogenerated charges is greater. In addition, in order to ensure that the intermediate electrons can be rapidly transferred to two sides, the middle of the photodiode is doped with a different doping material from the floating diffusion node. For example, for the floating diffusion node, a silicon substrate is doped with a group-V element in the chemical periodic table, which may be N, P, As and other elements. Further, the middle region of the photodiode is doped with a group-III element, such as B, Al, Ga or In, to obtain a potential raised middle region, which is referred to as a potential adjustment region for assisting rapid transfer of the transmission gate group. In this way, it is equivalent to setting an electron repulsion region in the middle region. Furthermore, with the relative arrangement of the transmission gate units, it is equivalent to constructing two electron ramps when conducting, and the photogenerated charges can be rapidly transferred to two directions, greatly improving the electron transfer efficiency.

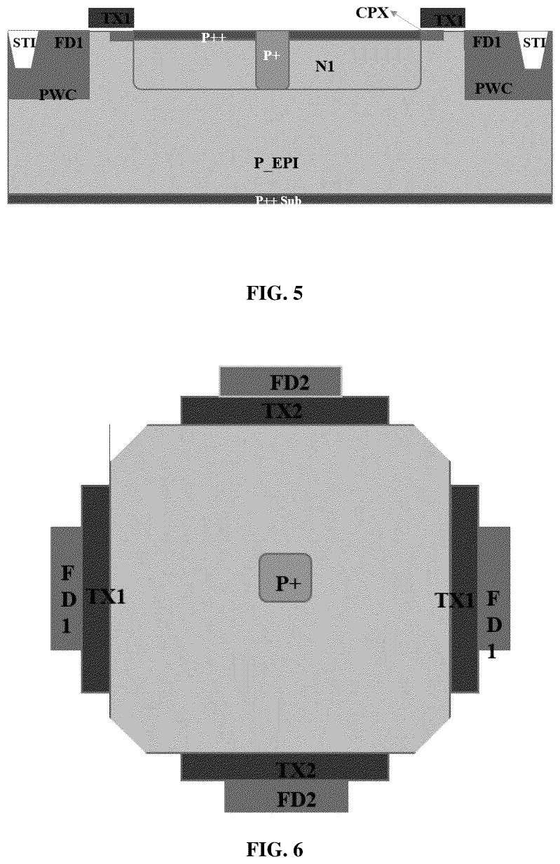

FIG. 5 is a sectional view of the sensor unit for depth information acquisition according to the embodiment of the present disclosure, which shows a sectional structure taken along a dashed line in FIG. 4. The epitaxial layer is implemented by a P-type epitaxial layer doped with a group-III element. The PDN photoelectric conversion region is formed by doping a group-V element on the P-type epitaxial layer, and the surface of the P-type epitaxial layer is covered with a P-type doping region having a higher doping concentration than the epitaxial layer to form surface clamp. Furthermore, the middle of the photoelectric region of the PDN is doped with a P-type doping concentration greater than the P doping concentration of the epitaxial layer and less than the P doping concentration of the surface clamp, to form a doping region for assisting the rapid transfer of electrons, i.e., the potential adjustment region in the middle, which optimally penetrates the PDN region in the view of the depth, so as to ensure the rapid transfer of generated electrons. Further, the proportion of the doping region occupying the total PDN area is optimally set between 5% and 15%, which can ensure that the photoelectric conversion efficiency of the device is not affected. The doping depth thereof is not limited to the penetration, and may be set to more than half of the N-type doping depth in the PDN, which is not limited to be realized by this structure. In order to ensure the direction of charge transfer and the opposite arrangement characteristic of the transmission gates, a line connecting the at least two transmission gate units symmetrically arranged is parallel to one of center lines of the photodiode unit, so as to ensure the correct direction of the formed potential elevation for the charge transfer acceleration, and ensure the accurate and efficient charge transfer.

FIG. 6 is a schematic diagram showing a sensor unit for depth information acquisition according to another embodiment of the present disclosure, which differs from FIG. 5 in that the epitaxial layer is doped with a N-type material of a V-group element, so that the photoelectric conversion efficiency can be increased, that is, more photogenerated charges can be generated. With the structure of the present disclosure, the design advantages of the present disclosure can be reflected to a greater extent, and more photogenerated charges become effective photogenerated charges, improving the detection efficiency and the detection quality of the image sensor unit.

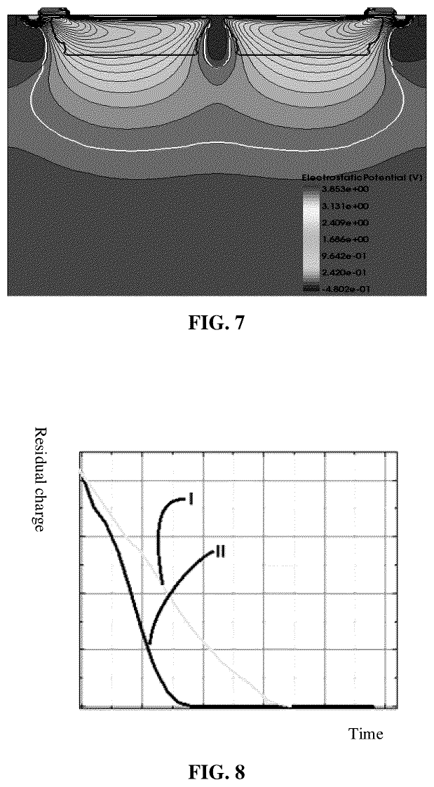

FIG. 7 is a schematic diagram showing an effect of the sensor unit for depth information acquisition according to the embodiment of the present disclosure. It can be seen from the drawing that, a more balanced transfer electric field can be formed as far as possible with the solution in the present disclosure, so that the photogenerated charges generated in the photoelectric conversion region can be rapidly transferred to the two transmission gate units symmetrically arranged on the two sides.

In order to further illustrate the technical effect of the present disclosure, FIG. 8 shows a quantitative comparison. Compared with a traditional solution of a single transmission gate, the electrons can be rapidly transferred with the solution in the present disclosure. In FIG. 8, a curve I shows a relationship between the amount of residual charges in the charge accumulation region of the transmission gate diode and a time in the conventional technology, and a curve II shows a relationship between the amount of residual charges in the charge accumulation region of the transmission gate diode and a time with the present solution. The actual experimental parameters are not given. The actual measurement result is, for example, that the proportion of the residual charges in the present disclosure is only about 5% in Ins time, while the proportion of the residual charges in the conventional technology is about 40% in the same time. In comparison, the requirements of the efficient and accurate detection can be better met with the solution of the present disclosure, which exemplarily illustrates the advantages of the effect and not necessarily limits the values listed above.

FIG. 9 is a schematic diagram showing a sensor unit for depth information acquisition according to another embodiment of the present disclosure, which is described corresponding to the embodiment shown in FIG. 3 that each transmission gate group includes four transmission gate units. By further increasing the number of transmission gate units in the transmission gate group, the transfer speed of photogenerated charges can be further increased. As shown in FIG. 9, the transmission gates are arranged in the photoelectric conversion region, the transmission gate units that are the same as each other are alternatively arranged, and spaces between the units are generally the same, forming the uniform arrangement effect. Furthermore, with the doping region for assisting the rapid electron transfer arranged in the middle, a similar lifting effect to the two units can be achieved. In order to ensure the accuracy of the electron transfer, the center line of the doping region is not parallel to the center line of the photoelectric conversion region. In order to ensure the balance of electron transfer in the directions and conform to the existing shape of the photoelectric conversion region, the optimal number of transmission gate units in each transmission gate group should be set as being even, so as to ensure that the photogenerated charges can be transferred more efficiently without changing the shape of the existing photoelectric conversion region. Other parts similar to those shown FIGS. 4 and 5 are not described in detail herein.

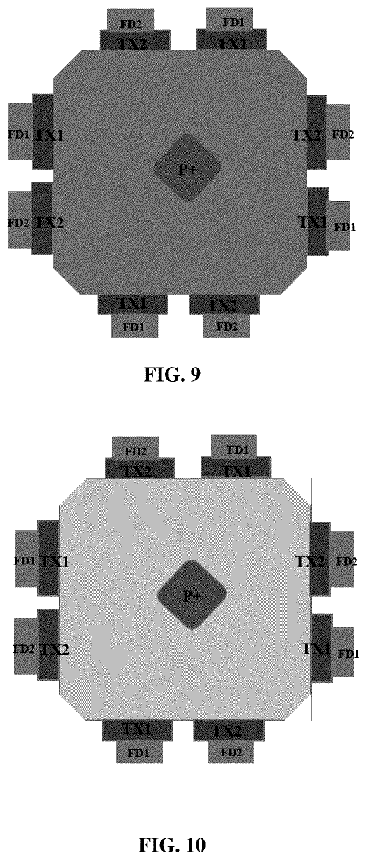

The embodiment shown FIG. 10 has a same basic function as that of FIG. 9, but differs from FIG. 9 in that the epitaxial layer in FIG. 10 is an N-type epitaxial layer, by which a higher photogenerated charge conversion efficiency can be achieved. Similar to FIG. 6, the structure in the present disclosure has a more optimized adaptability effect for the structure of the N-type epitaxial layer, which is not described in detail herein.

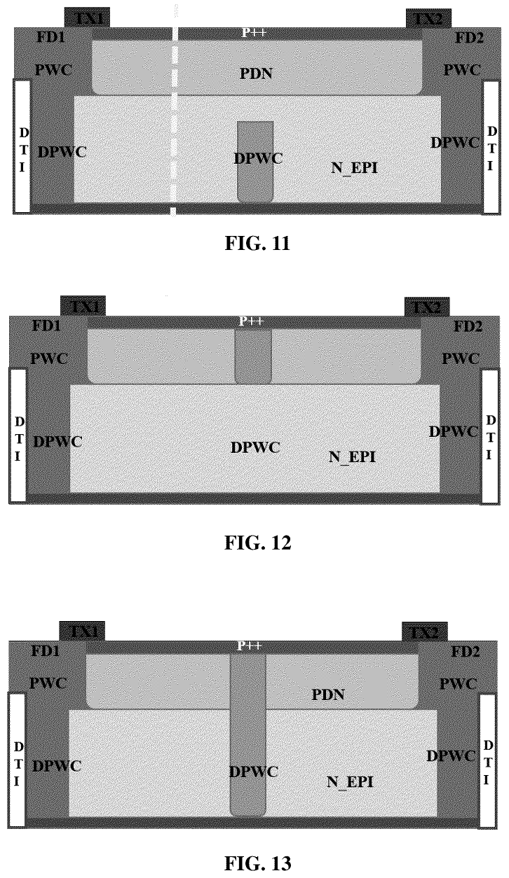

The following description id given in combination with the profile structure of FIG. 10 for further explanation. FIGS. 11 to 13 are schematic diagrams showing doping regions for assisting transfer respectively set in different sensor units according to embodiments of the present disclosure. An N-type epitaxial substrate is formed by doping an N-type material in the substrate layer. A PDN conversion region with the same function as P-type doping is located at the upper part of the substrate. There are P-well regions with P-type doping around the substrate and PDN. In order to assist the photogenerated charges to be rapidly transferred to the corresponding floating diffusion node through multiple transmission gate units with the structure of the transmission gate group, the doping region for assisting transfer may be arranged in three different structures respectively shown in FIG. 11 to 13, where the doping concentration thereof is less than the P-type doping concentration in the surface clamp and is greater than the doping concentration of the P-type material in the P-well. In FIG. 11, the doping region for assisting transfer is mainly set in N-type epitaxy, and has a depth greater than ½ of the depth of N-type epitaxy layer, which raises the intermediate potential while not occupying the area of the main photoelectric conversion region, thereby ensuring the two important parameters of the photogenerated charge efficiency and the photoelectric transfer efficiency. In FIG. 12, the doping region for assisting transfer is arranged in the conversion region PDN, which is similar to the solution of the doping region for assisting transfer in the P-type substrate shown in FIG. 5, and is not repeated herein. FIG. 13 shows a solution that the doping region for assisting transfer is arranged through the epitaxy and the conversion region PDN, improving the charge transfer efficiency to a greater extent compared with FIG. 11 and FIG. 12. With this structure, for example, the cross-sectional area can be set smaller than that in FIG. 12, so that both the photoelectric conversion efficiency and the charge transfer speed rate can be improved, which is not limited herein.

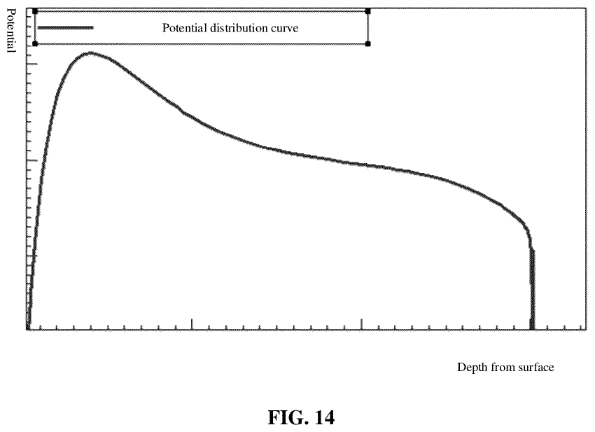

Furthermore, in order to ensure the photoelectric transfer efficiency, the N-type epitaxial layer shown in FIGS. 10 to 13 and FIG. 6 is further connected with an auxiliary depletion layer. The auxiliary depletion layer is made of Al₂O₃, HaO₂ and other negative electrical materials. The auxiliary depletion layer, on the one hand, can assist the N-type epitaxial photodiode to form a fully depleted device, and on the other hand, can raise the potential of the adjacent side of the epitaxial layer in the present disclosure. For example, the potential measurement is performed at the position shown in FIG. 11, and the result is shown in FIG. 14, where a parameter of a depth from the surface in a horizontal axis denotes the depth from the upper surface of FIG. 11. That is, by arranging the auxiliary depletion layer, the potential of the part connected with the auxiliary depletion layer is raised, which has a similar effect to the doping region for assisting transfer that is doped with a P-type maternal, so that the photogenerated charges can be rapidly transferred in the longitudinal direction, which is not described in detail herein.

It should be noted that, relational terms such as “first” and “second” herein are only used to distinguish one entity or operation from another entity or operation, and do not necessarily require or imply there is such actual relationship or sequence between these entities or operations. Moreover, terms “comprising”, “including” or any other variations thereof are intended to encompass a non-exclusive inclusion, such that a process, a method, an article or a device including a series of elements includes not only those elements, but also includes other elements that are not explicitly listed or inherent to such the process, method, article or device. Without further limitation, an element defined by a phrase “including a . . . ” does not preclude the presence of additional identical elements in a process, method, article or device including the element.

Preferred embodiments of the present disclosure are given in the above description, and are not intended to limit the present disclosure. For those skilled in the art, the present disclosure may have various modifications and changes. Any modifications, equivalents and improvements made in the spirit and principle of the present disclosure should be included in the protection scope of the present disclosure. It should be noted that similar numerals and letters refer to similar items in the following drawings. Therefore, if an item is defined in a drawing, the item is not required to be further defined and explained in subsequent drawings. Preferred embodiments of the present disclosure are given in the above description, and are not intended to limit the present disclosure. For those skilled in the art, the present disclosure may have various modifications and changes. Any modifications, equivalents and improvements made in the spirit and principle of the present disclosure should be included in the protection scope of the present disclosure.

1. An image sensor, comprising:
a photodiode unit, configured to receive a return light signal reflected back by a detected target, wherein the photodiode unit is electrically connected with at least one storage unit via one or more transmission gate groups for a part of a time period to transfer photogenerated charges converted by the return light signal to the at least one storage unit, and wherein each of the one or more transmission gate groups comprises at least two transmission gate units.

2. The image sensor according to claim 1, further comprising:
a potential adjustment region, configured to accelerate the transfer of the photogenerated charges to the storage unit.

3. The image sensor according to claim 1, wherein the number of the one or more transmission gate groups is two, and the number of the at least one storage unit is two.

4. The image sensor according to claim 1, wherein gates of the at least two transmission gate units in a same transmission gate group are connected together and are used to receive a same control signal.

5. The image sensor according to claim 1, wherein the storage unit is doped with a first type, and the image sensor further comprises an epitaxial layer doped with a second type different from the doping type of the storage unit.

6. The image sensor according to claim 1, wherein the storage unit is doped with a first type, and the image sensor further comprises an epitaxial layer doped with the first type the same as the doping type of the storage unit.

7. The image sensor according to claim 6, wherein the epitaxial layer of the first type is further connected with an auxiliary depletion layer.

8. The image sensor according to claim 1, wherein the number of the at least two transmission gate units in a same transmission gate group is even.

9. The image sensor according to claim 8, wherein the even number of transmission gate units in the same transmission gate group are symmetrically arranged on two sides of the photodiode unit.

10. The image sensor according to claim 9, wherein a line connecting the at least two transmission gate units symmetrically arranged is parallel to one of center lines of the photodiode unit.

11. The image sensor according to claim 3, wherein control signals respectively for the two transmission gate groups are complementary.

12. The image sensor according to claim 2, wherein the potential adjustment region is a doping region doped with a second type.

13. The image sensor according to claim 5, wherein the potential adjustment region is located in the epitaxial layer.

14. The image sensor according to claim 5, wherein the potential adjustment region is provided between the epitaxial layer and a first surface of the image sensor opposite to the epitaxial layer.

15. The image sensor according to claim 5, wherein the potential adjustment region extends from a first surface of the image sensor opposite to the epitaxial layer to a second surface of the image sensor.
